(19) United States
(12) Patent Application Publication
(10) Pub. No.: US 2026/0247718 A1
(43) Pub. Date: Aug. 20, 2026

(54) SEMICONDUCTOR DEVICE AND METHOD OF MANUFACTURING THE SAME

(71) Applicant: ABLIC INC., Nagano (JP)

(72) Inventor: Tetsuya SAKUMA, Nagano (JP)

(21) Appl. No.: 19/534,701

(22) Filed: Feb. 9, 2026

(30) Foreign Application Priority Data
Feb. 18, 2025 (JP) 2025-023950
Sep. 30, 2025 (JP) 2025-163229

(51) Int. Cl. H10D 86/60; H10W 20/00

(52) U.S. Cl. CPC H10D 86/60; H10W 20/023; H10W 20/081; H10W 20/084; H10W 20/085

(57) ABSTRACT

Provided is a semiconductor device including: a first wiring layer formed on a surface of a semiconductor substrate; an interlayer insulating film formed in a layer above the first wiring layer; an etching stopper film formed in a layer above the interlayer insulating film; an insulating film formed in a layer above the etching stopper film, the insulating film including a thick film portion and an inclined portion; a metal film formed in a layer above the insulating film; a protective film formed in a layer above the metal film; and a pad opening portion formed in the protective film such that a part of the metal film is exposed, the pad opening portion being formed at a position overlapping the thick film portion in plan view.

### CROSS-REFERENCE TO RELATED APPLICATION

This application claims priority benefits of Japanese application no. 2025-023950, filed on Feb. 18, 2025, and Japanese application no. 2025-163229, filed on Sep. 30, 2025. The entirety of each of the above-mentioned patent applications is hereby incorporated by reference herein and made a part of this specification.

### BACKGROUND OF THE INVENTION

### 1. Field of the Invention

The present invention relates to a semiconductor device and a method of manufacturing the same.

### 2. Description of the Related Art

In order for a semiconductor device to exchange electric signals with the outside, a pad of the semiconductor device and an external connection terminal are connected to each other with a metal wire through use of a wire bonding technology. The wire bonding technology is a mechanical process for bonding the wire made of gold or the like to the pad of the semiconductor device through use of heat, ultrasonic waves, and pressure. Mechanical stress is applied to the pad and a layer below the pad. Cracks sometimes occur in an insulating film in the layer below the pad because of this mechanical stress. Further, a semiconductor element in a layer below the pad is sometimes damaged to reduce the reliability of the semiconductor device.

In order to suppress the occurrence of the cracks in the insulating film in the layer below the pad, for example, in the invention as described in Japanese Patent Application Laid-open No. Hei 11-186320, the following semiconductor device is described. In the semiconductor device, in a layer below a third conductive pad provided with a pad opening portion, a first conductive pad and a second conductive pad are provided along an edge of the pad opening portion (see, for example, Japanese Patent Application Laid-open No. Hei 11-186320).

However, there is room for improvement in the invention as described in Japanese Patent Application Laid-open No. Hei 11-186320 in that three or more layers of metal films are required to be formed.

### SUMMARY OF THE INVENTION

The present invention has been made in view of the above-mentioned circumstances, and has an object to provide, in at least one aspect of the present invention, a semiconductor device capable of suppressing occurrence of cracks in an insulating film in a layer below a pad opening portion even in the semiconductor device including two layers of metal films.

A semiconductor device according to at least one embodiment of the present invention includes: a first wiring layer formed on a surface of a semiconductor substrate; an interlayer insulating film formed in a layer above the first wiring layer; an etching stopper film formed in a layer above the interlayer insulating film; an insulating film formed in a layer above the etching stopper film, the insulating film including a thick film portion and an inclined portion; a metal film formed in a layer above the insulating film; a protective film formed in a layer above the metal film; and a pad opening portion formed in the protective film such that a part of the metal film is exposed, the pad opening portion being formed at a position overlapping the thick film portion in plan view.

A method of manufacturing a semiconductor device according to at least one embodiment of the present invention includes: forming a first wiring layer on a surface of a semiconductor substrate; forming an interlayer insulating film in a layer above the first wiring layer; forming an etching stopper film in a layer above the interlayer insulating film; forming an insulating film in a layer above the etching stopper film, forming a photoresist film in a layer above the insulating film, and forming a thick film portion and an inclined portion by etching the insulating film with the photoresist film being used as a mask; forming a metal film in a layer above the insulating film; forming a protective film in a layer above the metal film; and forming a pad opening portion in the protective film at a position overlapping the thick film portion in plan view such that a part of the metal film is exposed.

According to the at least one aspect of the present invention, it is possible to provide the semiconductor device capable of suppressing occurrence of cracks in the insulating film in the layer below the pad opening portion even in the semiconductor device including two layers of metal films.

### BRIEF DESCRIPTION OF THE DRAWINGS

FIG. 1 is a schematic cross-sectional view of a semiconductor device according to a first embodiment of the present invention.

FIG. 2 is a view for illustrating a manufacturing step for the semiconductor device according to the first embodiment of the present invention.

FIG. 3 is a view for illustrating a manufacturing step for the semiconductor device according to the first embodiment of the present invention, following FIG. 2.

FIG. 4 is a view for illustrating a manufacturing step for the semiconductor device according to the first embodiment of the present invention, following FIG. 3.

FIG. 5 is a view for illustrating a manufacturing step for the semiconductor device according to the first embodiment of the present invention.

FIG. 6 is a schematic cross-sectional view of a semiconductor device according to a first modification example of the first embodiment of the present invention.

FIG. 7 is a schematic cross-sectional view of a semiconductor device according to a second modification example of the first embodiment of the present invention.

FIG. 8 is a schematic cross-sectional view of a semiconductor device according to a third modification example of the first embodiment of the present invention.

### DESCRIPTION OF THE EMBODIMENTS

In the following, at least one embodiment for carrying out the present invention is described in detail with reference to the drawings. The same components are denoted by the same reference symbols in the drawings, and overlapping description thereof is omitted in some cases.

Moreover, an X-axis, a Y-axis, and a Z-axis illustrated in the drawings are orthogonal to one another. In some cases, a Z-axis direction is referred to as "height direction" or "thickness direction." In some cases, a +Z-axis direction is referred to as "upper side," and a −Z-axis direction is referred to as "lower side." In some cases, a surface of each member on the +Z direction side is referred to as "front surface" or "upper surface," and a surface thereof on the −Z direction side is referred to as "back surface" or "lower surface." The phrase "in plan view" refers to viewing each member from the +Z direction side toward the −Z direction side.

Moreover, the drawings are merely schematic, and, for example, a ratio among width, depth, and thickness is not necessarily drawn to scale. The numbers, positions, shapes, structures, dimensions, and the like of respective members are not limited to those described in the following at least one embodiment, and can be set to numbers, positions, shapes, structures, dimensions, and the like that are preferred in carrying out the present invention.

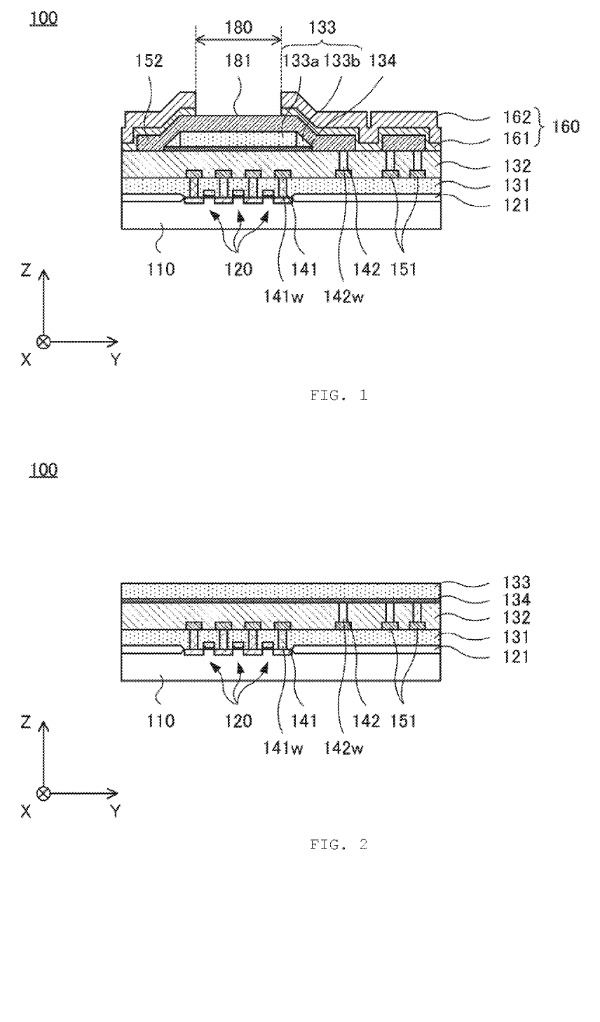

FIG. 1 is a schematic cross-sectional view of a semiconductor device according to a first embodiment of the present invention. As illustrated in FIG. 1, a semiconductor device 100 according to the first embodiment of the present invention includes a semiconductor substrate 110, a first wiring layer 151, an interlayer insulating film 132, an etching stopper film 134, an insulating film 133, a metal film 152, a protective film 160, and a pad opening portion 180.

A MOS transistor 120 serving as a semiconductor element is formed at a predetermined position on a surface of the semiconductor substrate 110. An element isolation insulating film 121 is formed in a region on the surface of the semiconductor substrate 110 in which the MOS transistor 120 is not formed. The element isolation insulating film 121 is a LOCOS oxide film in the first embodiment.

An intermediate insulating film 131 is formed in a layer above the MOS transistor 120 and the element isolation insulating film 121. The intermediate insulating fil m 131 is, for example, a silicon oxide film. The first wiring layer 151 is formed at a predetermined position in a layer above the intermediate insulating film 131. The first wiring layer 151 is, for example, an aluminum alloy film such as Al-Cu, or a laminated film of an aluminum alloy film and titanium nitride.

A contact 141 is formed at a predetermined position in the intermediate insulating film 131. A conductive substance 141w is embedded in the contact 141. The conductive substance 141w is, for example, titanium, titanium nitride, or tungsten. The conductive substance 141w may be formed of the same material as that of the first wiring layer 151. The MOS transistor 120 is connected to the first wiring layer 151 through the contact 141. The interlayer insulating film 132 is formed in a layer above the intermediate insulating film 131 and the first wiring layer 151.

A connection hole 142 is formed at a predetermined position in the interlayer insulating film 132 in a region in which the etching stopper film 134 and an insulating film 133 to be described later are not formed, and a conductive substance 142w is embedded in the connection hole 142. The conductive substance 142w is, for example, titanium, titanium nitride, or tungsten. The conductive substance 142w may be formed of the same material as that of the metal film 152. Here, the connection hole 142 and the conductive substance 142w are easily processed and the manufacturing cost can be suppressed because the connection hole 142 is formed in a region in which the insulating film 133 is not formed.

The etching stopper film 134 is formed in a layer below the insulating film 133 to be described later in a layer above the interlayer insulating film 132. A material of the etching stopper film 134 is only required be a material having a large selectivity with respect to the insulating film 133 to be described later and a small etching amount at the time of etching the insulating film 133, and is a silicon nitride film in the first embodiment.

The insulating film 133 is formed in a layer above the etching stopper film 134. The insulating film 133 is a silicon oxide film in the first embodiment. The insulating film 133 includes a thick film portion 133a and an inclined portion 133b having an upper surface inclined such that the thickness gradually decreases around the thick film portion 133a. A lower surface of the thick film portion 133a and a lower surface of the inclined portion 133b are formed to be flush with each other. In the first embodiment, the upper surface of the inclined portion 133b is an inclined flat surface, but the upper surface may be formed in a rounded arc shape as in a first modification example to be described later. It is preferred that the thickness of the thick film portion 133a be from 500 nm to 1,000 nm.

The metal film 152 serving as a second wiring layer is formed at a predetermined position in a layer above the interlayer insulating film 132 and the insulating film 133. The metal film 152 is, for example, an aluminum alloy film such as Al-Cu, or a laminated film of an aluminum alloy film and titanium nitride. The thickness of the metal film 152 may be appropriately changed. The metal film 152 is connected to the first wiring layer 151 through the connection hole 142.

The protective film 160 is formed in a layer above the metal film 152. The protective film 160 is formed of a laminated film of a silicon oxide film 161 and a silicon nitride film 162 in the first embodiment.

The pad opening portion 180 is formed at a predetermined position in the protective film 160. A portion of a surface of the metal film 152 is exposed by the pad opening portion 180. The pad opening portion 180 is formed at a position overlapping the thick film portion 133a in plan view. The exposed portion of the surface of the metal film 152 becomes a pad 181. A conductive wire is attached to the pad 181 by the wire bonding technology. The pad 181 is thus electrically connected to another semiconductor device or the like (not shown).

The semiconductor device 100 can thus form the insulating film 133 in the layer below the pad opening portion 180. Accordingly, the semiconductor device 100 can suppress the occurrence of cracks in the insulating film in the layer below the pad opening portion 180 even in the semiconductor device including two layers of metal films.

Now, a method of manufacturing the semiconductor device 100 is described with reference to FIGS. 2 to 4.

As illustrated in FIG. 2, the element isolation insulating film 121 and the MOS transistor 120 are formed on the surface of the semiconductor substrate 110 by a publicly-known technology. Next, the intermediate insulating film 131 is formed in a layer above the element isolation insulating film 121 and the MOS transistor 120 through use of a CVD method. An upper surface of the intermediate insulating film 131 is planarized through use of a CMP method. The contact 141 is formed at a predetermined position in the intermediate insulating film 131 through use of a photolithography technology and a dry etching technology. The conductive substance 141w is embedded in the contact 141 through use of a sputtering method, the CVD method, or the like.

Next, the first wiring layer 151 is deposited in a layer above the intermediate insulating film 131 and the contact 141 through use of the sputtering method. Then, the first wiring layer 151 is formed at a predetermined position through use of the photolithography technology and the dry etching technology. After that, the interlayer insulating film 132 is formed in a layer above the intermediate insulating film 131 and the first wiring layer 151 through use of the CVD method. An upper surface of the interlayer insulating film 132 is then planarized through use of the CMP method. After that, as required, a film made of the same material as that of the interlayer insulating film 132 may be laminated so that the film thickness of the interlayer insulating film 132 is adjusted to a predetermined thickness.

Next, the connection hole 142 is formed at a predetermined position in the interlayer insulating film 132 through use of the photolithography technology and the dry etching technology. The conductive substance 142w is embedded in the connection hole 142 through use of the sputtering method, the CVD method, or the like. The connection hole 142 and the conductive substance 142w can be easily processed and the manufacturing cost can be suppressed because the connection hole 142 is formed in a region in which the insulating film 133 is not formed. After that, the etching stopper film 134 is formed in a layer above the interlayer insulating film 132 through use of the CVD method. The insulating film 133 is formed to have the thickness of the thick film portion 133a in a layer above the etching stopper film 134 through use of the CVD method.

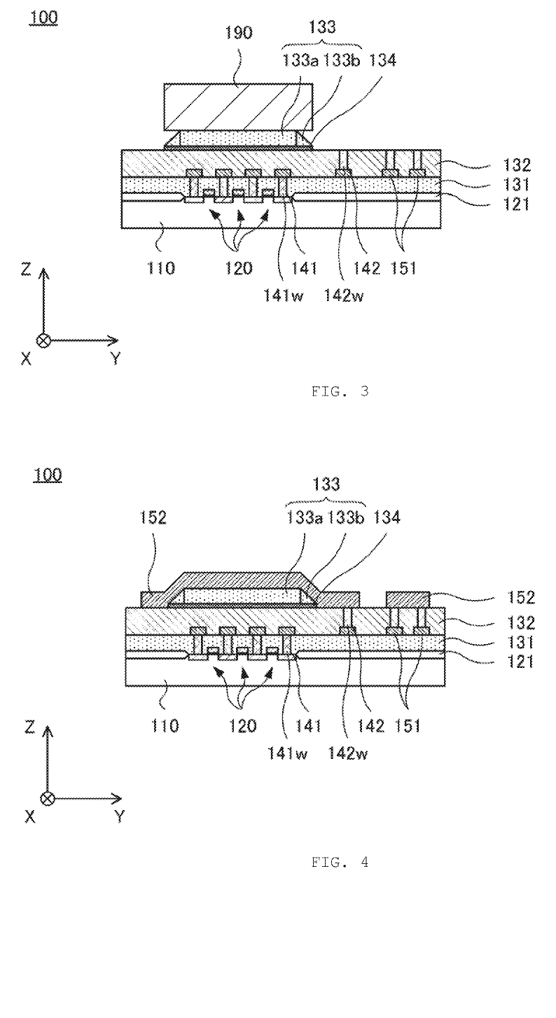

Next, as illustrated in FIG. 3, a photoresist film 190 is formed at a predetermined position in a layer above the insulating film 133 formed to have the thickness of the thick film portion 133a. Next, the thick film portion 133a and the inclined portion 133b in the insulating film 133 are formed through use of an etching technology with the photoresist film 190 remaining in the layer above the insulating film 133 being used as a mask. At this time, etching is prevented from progressing to the underlying interlayer insulating film 132 by the etching stopper film 134. This facilitates the etching of the insulating film 133. Examples of the etching technology include isotropic wet etching using a chemical solution, isotropic chemical dry etching, and anisotropic dry etching. Further, the inclined portion 133b may also be formed through use of anisotropic dry etching after isotropic wet etching or chemical dry etching is used. After that, the etching stopper film 134 is removed through use of the etching technology, and the photoresist film 190 is removed through use of a chemical solution or an ashing technology.

In the case of forming the inclined portion 133b through use of anisotropic dry etching, a side wall protective film which is a reaction product of the photoresist film and an etching gas adheres to a surface exposed by the etching of the insulating film 133 during an etching process. The inclined portion 133b can be formed by adjusting this side wall protective film.

Next, as illustrated in FIG. 4, the metal film 152 is deposited in a layer above the insulating film 133 and the connection hole 142 through use of the sputtering method, and then the metal film 152 is formed at a predetermined position through use of the photolithography technology and the dry etching technology.

After that, the protective film 160 is formed by laminating the silicon oxide film 161 and the silicon nitride film 162 in a layer above the insulating film 133 and the metal film 152 through use of the CVD method. Finally, the pad opening portion 180 is formed at a position overlapping the thick film portion 133a in plan view through use of the photolithography technology and the dry etching technology. Thus, the semiconductor device 100 can be manufactured.

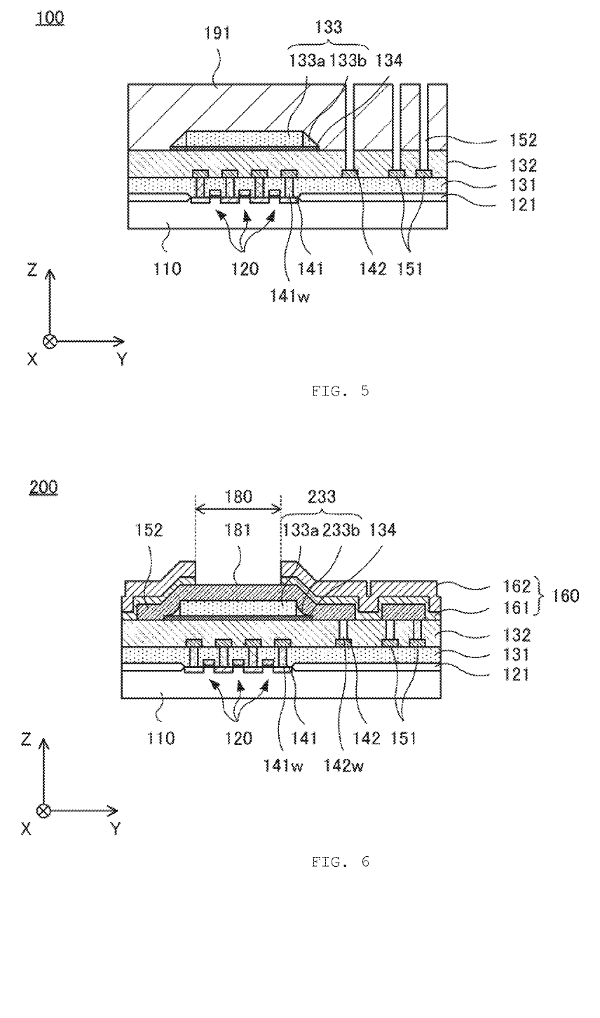

The connection hole 142 may be formed after the insulating film 133 is formed. As illustrated in FIG. 5, the connection hole 142 is formed at a predetermined position in the interlayer insulating film 132 through use of the photolithography technology and the dry etching technology. After that, a photoresist film 191 is removed through use of a chemical solution or the ashing technology. Subsequently, the conductive substance 142w is embedded in the connection hole 142 through use of the sputtering method, the CVD method, or the like so that the metal film 152 is formed at a predetermined position.

FIG. 6 is a schematic cross-sectional view for illustrating a semiconductor device according to a first modification example of the first embodiment. As illustrated in FIG. 6, a semiconductor device 200 according to the first modification example of the first embodiment is similar to that of the first embodiment, except that an upper surface of an inclined portion 233b of an insulating film 233 is formed in a rounded arc shape.

The insulating film 233 can be formed in a layer below the pad opening portion 180 in the configuration of FIG. 6 as well. Accordingly, the semiconductor device 200 according to the first modification example of the first embodiment of the present invention can suppress the occurrence of cracks in the insulating film in the layer below the pad opening portion 180 even in the semiconductor device including two layers of metal films.

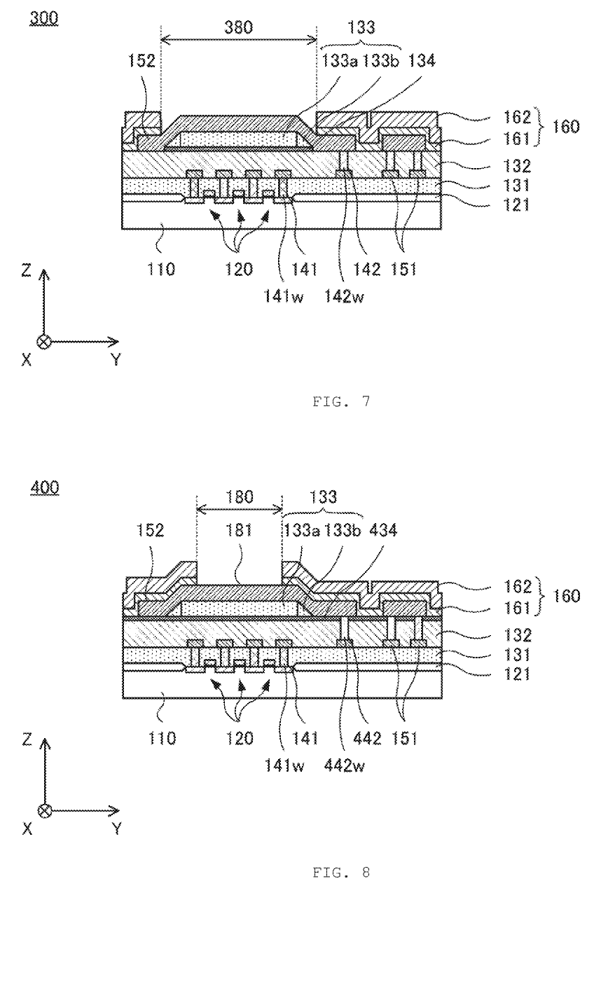

FIG. 7 is a schematic cross-sectional view for illustrating a semiconductor device according to a second modification example of the first embodiment. As illustrated in FIG. 7, a semiconductor device 300 according to the second modification example of the first embodiment is similar to that of the first embodiment, except that a pad opening portion 380 is formed so that the thick film portion 133a and the inclined portion 133b are inside the pad opening portion 380 in plan view.

The insulating film 133 can be formed in a layer below the pad opening portion 380 in the configuration illustrated in FIG. 7 as well. Accordingly, the semiconductor device 300 according to the second modification example of the first embodiment of the present invention can suppress the occurrence of cracks in the insulating film in the layer below the pad opening portion 380 even in the semiconductor device including two layers of metal films.

FIG. 8 is a schematic cross-sectional view for illustrating a semiconductor device according to a third modification example of the first embodiment. As illustrated in FIG. 8, a semiconductor device 400 according to the third modification example of the first embodiment is similar to that of the first embodiment, except that an etching stopper film 434 is formed in the entire layer above the interlayer insulating film 132.

Thus, the semiconductor device 400 according to the third modification example of the first embodiment can omit the step of removing the etching stopper film 434. This allows the manufacturing cost to be reduced.

In the method of manufacturing the semiconductor device 100 of the first embodiment, the etching stopper film 134 is formed after the connection hole 142 is formed, but, in the method of manufacturing the semiconductor device 400 of the third modification example, a connection hole 442 is formed after the etching stopper film 434, the thick film portion 133a, and the inclined portion 133b are formed, under a state in which the etching stopper film 434 is left. The rest of the method is similar to that of the first embodiment.

The insulating film 133 can be thickened in the layer below the pad opening portion 180 in the configuration illustrated in FIG. 8 as well. Accordingly, the semiconductor device 400 according to the third modification example of the first embodiment of the present invention can suppress the occurrence of cracks in the insulating film in the layer below the pad opening portion 180 even in the semiconductor device including two layers of metal films.

The at least one embodiment of the present invention has been described above, but the present invention is not limited to the at least one embodiment. Designs and the like not departing from the gist of the present invention are also included in the present invention.

For example, the semiconductor element is a MOS transistor in the at least one embodiment, but the semiconductor element is not limited thereto. The semiconductor element may be another element. Further, the LOCOS oxide film is used for the element isolation insulating film in the at least one embodiment, but shallow trench isolation (STI) may be used instead. The interlayer insulating film may be a laminated film for covering the planarized upper surface with an insulating film. The protective film is a laminated film of a silicon oxide film and a silicon nitride film in the at least one embodiment, but the protective film is not limited thereto. The protective film may be formed of another material, or may be another laminated structure.

What is claimed is:

1. A semiconductor device, comprising:
a first wiring layer formed on a surface of a semiconductor substrate;
an interlayer insulating film formed in a layer above the first wiring layer;
an etching stopper film formed in a layer above the interlayer insulating film;
an insulating film formed in a layer above the etching stopper film, the insulating film including a thick film portion and an inclined portion;
a metal film formed in a layer above the insulating film;
a protective film formed in a layer above the metal film; and
a pad opening portion formed in the protective film such that a part of the metal film is exposed, the pad opening portion being formed at a position overlapping the thick film portion in plan view.

2. The semiconductor device according to claim 1, further comprising a semiconductor element formed on the surface of the semiconductor substrate, the semiconductor element being formed below the pad opening portion in plan view.

3. The semiconductor device according to claim 1, wherein the inclined portion has an upper surface formed in an arc shape.

4. The semiconductor device according to claim 3, further comprising a semiconductor element formed on the surface of the semiconductor substrate, the semiconductor element being formed below the pad opening portion in plan view.

5. The semiconductor device according to claim 1, further comprising a connection hole formed in the interlayer insulating film in a region in which the insulating film is not formed in the layer above the etching stopper film.

6. The semiconductor device according to claim 5, further comprising a semiconductor element formed on the surface of the semiconductor substrate, the semiconductor element being formed below the pad opening portion in plan view.

7. A method of manufacturing a semiconductor device, the method comprising:
forming a first wiring layer on a surface of a semiconductor substrate;
forming an interlayer insulating film in a layer above the first wiring layer;
forming an etching stopper film in a layer above the interlayer insulating film;
forming an insulating film in a layer above the etching stopper film, forming a photoresist film in a layer above the insulating film, and forming a thick film portion and an inclined portion by etching the insulating film with the photoresist film being used as a mask;
forming a metal film in a layer above the insulating film;
forming a protective film in a layer above the metal film; and
forming a pad opening portion in the protective film at a position overlapping the thick film portion in plan view such that a part of the metal film is exposed.

8. The method of manufacturing a semiconductor device according to claim 7, further comprising, before the forming of the etching stopper film, forming a semiconductor element on the surface of the semiconductor substrate at a position overlapping the thick film portion in plan view.

9. The method of manufacturing a semiconductor device according to claim 7, wherein the etching is wet etching.

10. The method of manufacturing a semiconductor device according to claim 9, further comprising, before the forming of the etching stopper film, forming a semiconductor element on the surface of the semiconductor substrate at a position overlapping the thick film portion in plan view.

11. The method of manufacturing a semiconductor device according to claim 7, wherein the etching is chemical dry etching.

12. The method of manufacturing a semiconductor device according to claim 11, further comprising, before the forming of the etching stopper film, forming a semiconductor element on the surface of the semiconductor substrate at a position overlapping the thick film portion in plan view.

13. The method of manufacturing a semiconductor device according to claim 7, wherein the etching is dry etching.

14. The method of manufacturing a semiconductor device according to claim 13, further comprising, before the forming of the etching stopper film, forming a semiconductor element on the surface of the semiconductor substrate at a position overlapping the thick film portion in plan view.

15. The method of manufacturing a semiconductor device according to claim 7, wherein the etching comprises performing dry etching after performing one of wet etching or chemical dry etching.

16. The method of manufacturing a semiconductor device according to claim 15, further comprising, before the forming of the etching stopper film, forming a semiconductor element on the surface of the semiconductor substrate at a position overlapping the thick film portion in plan view.

17. The method of manufacturing a semiconductor device according to claim 7, further comprising, before the forming of the etching stopper film, forming a connection hole in the interlayer insulating film in a region in which the insulating film is not formed.

18. The method of manufacturing a semiconductor device according to claim 17, further comprising, before the forming of the etching stopper film, forming a semiconductor element on the surface of the semiconductor substrate at a position overlapping the thick film portion in plan view.
